(19) United States
(12) Patent Application Publication
(10) Pub. No.: US 2024/0055383 A1
(43) Pub. Date: Feb. 15, 2024

(54) BUMP COPLANARITY FOR DIE-TO-DIE AND OTHER APPLICATIONS

(71) Applicant: QUALCOMM Incorporated, San Diego, CA (US)

(72) Inventors: Dongming HE, San Diego, CA (US); Hung-Yuan HSU, Taichung (TW); Yangyang SUN, San Diego, CA (US); Lily ZHAO, San Diego, CA (US)

(21) Appl. No.: 17/819,269

(22) Filed: Aug. 11, 2022

(51) Int. Cl. H01L 23/00

(52) U.S. Cl. CPC H01L 24/14; H01L 24/13; H01L 24/04; H01L 24/05; H01L 24/03; H01L 24/11; H01L 2224/0401; H01L 2224/03912; H01L 2224/0345; H01L 2224/05022; H01L 2224/05073; H01L 2224/05562; H01L 2224/05573; H01L 2224/1403; H01L 2224/14051; H01L 2224/13016; H01L 2224/13082; H01L 2224/13083; H01L 2224/13111; H01L 2224/13124; H01L 2224/13139; H01L 2224/13144; H01L 2224/13147; H01L 2224/13155; H01L 2224/11849; H01L 2224/11462; H01L 2224/11912

(57) ABSTRACT

Disclosed are techniques for selectively boosting conductive pillar bumps. In an aspect, an apparatus includes a plurality of metal pads, a first set of boosting pads attached to a first set of the plurality of metal pads, a first set of conductive pillar bumps attached to the first set of boosting pads, a second set of conductive pillar bumps attached to a second set of the plurality of metal pads, wherein heights of the first set of conductive pillar bumps are shorter than heights of the second set of conductive pillar bumps, and wherein heights of the first set of boosting pads plus the heights of the first set of conductive pillar bumps are within a tolerance threshold of the heights of the second set of conductive pillar bumps, and solder attached to the first set of conductive pillar bumps and the second set of conductive pillar bumps.

### BACKGROUND OF THE DISCLOSURE

### 1. Field of the Disclosure

Aspects of the disclosure relate generally to semiconductor fabrication, and more specifically, to improving bump coplanarity.

### 2. Description of the Related Art

Copper pillar bumps are used to connect various package components to the die in advanced packaging processes. Bump coplanarity is an important aspect of ensuring reliable connections. Bump coplanarity is essentially a measure of flatness, and more specifically, a measurement of the variation in bump height. A bump that is not tall enough will not connect to a package component, while one that is too tall may prevent the connections of neighboring bumps. As such, any height unevenness in a bump array may affect wafer probing, flip-chip assembly, electronics board assembly, and ultimately, reliability. Coplanarity becomes particularly important in the context of increasing bump densities in high-performance computing products and other advanced packaging applications.

Differences in bump height (i.e., coplanarity) may be a byproduct of the manufacturing process. For example, due to manufacturing tolerances, there may be some variation in the amount of copper deposited to build the copper pillars. Bump coplanarity may also depend on the bump density. For example, the same die may have different bump densities across different regions of the die (where different components are attached to the die in the different regions). Generally, smaller bumps allow for a smaller bump pitch (i.e., the center-to-center distance between bumps), while larger bumps need a larger pitch. As such, where the same die includes different regions having different bump densities, there may be a difference in coplanarity between the different bump regions.

### SUMMARY

The following presents a simplified summary relating to one or more aspects disclosed herein. Thus, the following summary should not be considered an extensive overview relating to all contemplated aspects, nor should the following summary be considered to identify key or critical elements relating to all contemplated aspects or to delineate the scope associated with any particular aspect. Accordingly, the following summary has the sole purpose to present certain concepts relating to one or more aspects relating to the mechanisms disclosed herein in a simplified form to precede the detailed description presented below.

In an aspect, an apparatus includes a plurality of metal pads; an under bump metallization (UBM) layer attached to the plurality of metal pads; a first set of boosting pads attached to a first portion of the UBM layer attached to a first set of the plurality of metal pads; a first set of conductive pillar bumps attached to the first set of boosting pads, wherein each conductive pillar bump of the first set of conductive pillar bumps is attached to a single boosting pad of the first set of boosting pads; a second set of conductive pillar bumps attached to a second portion of the UBM layer attached to a second set of the plurality of metal pads, wherein each conductive pillar bump of the second set of conductive pillar bumps is attached to a single metal pad of the second set of metal pads, wherein heights of the first set of conductive pillar bumps are shorter than heights of the second set of conductive pillar bumps, and wherein heights of the first set of boosting pads plus the heights of the first set of conductive pillar bumps are within a tolerance threshold of the heights of the second set of conductive pillar bumps; and solder attached to the first set of conductive pillar bumps and the second set of conductive pillar bumps.

In an aspect, a method of selectively boosting conductive pillar bumps includes attaching an under bump metallization (UBM) layer to a plurality of metal pads; attaching a first set of boosting pads to a first portion of the UBM layer attached to a first set of the plurality of metal pads; attaching a first set of conductive pillar bumps to the first set of boosting pads, wherein each conductive pillar bump of the first set of conductive pillar bumps is attached to a single boosting pad of the first set of boosting pads; attaching a second set of conductive pillar bumps to a second portion of the UBM layer attached to a second set of the plurality of metal pads, wherein each conductive pillar bump of the second set of conductive pillar bumps is attached to a single metal pad of the second set of metal pads, wherein heights of the first set of conductive pillar bumps are shorter than heights of the second set of conductive pillar bumps, and wherein heights of the first set of boosting pads plus the heights of the first set of conductive pillar bumps are within a tolerance threshold of the heights of the second set of conductive pillar bumps; and attaching solder to the first set of conductive pillar bumps and the second set of conductive pillar bumps.

In an aspect, a non-transitory computer-readable medium stores computer-executable instructions that, when executed by one or more apparatuses, cause the one or more apparatuses to: attach an under bump metallization (UBM) layer to a plurality of metal pads; attach a first set of boosting pads to a first portion of the UBM layer attached to a first set of the plurality of metal pads; attach a first set of conductive pillar bumps to the first set of boosting pads, wherein each conductive pillar bump of the first set of conductive pillar bumps is attached to a single boosting pad of the first set of boosting pads; attach a second set of conductive pillar bumps to a second portion of the UBM layer attached to a second set of the plurality of metal pads, wherein each conductive pillar bump of the second set of conductive pillar bumps is attached to a single metal pad of the second set of metal pads, wherein heights of the first set of conductive pillar bumps are shorter than heights of the second set of conductive pillar bumps, and wherein heights of the first set of boosting pads plus the heights of the first set of conductive pillar bumps are within a tolerance threshold of the heights of the second set of conductive pillar bumps; and attach solder to the first set of conductive pillar bumps and the second set of conductive pillar bumps.

Other objects and advantages associated with the aspects disclosed herein will be apparent to those skilled in the art based on the accompanying drawings and detailed description.

### BRIEF DESCRIPTION OF THE DRAWINGS

The accompanying drawings are presented to aid in the description of various aspects of the disclosure and are provided solely for illustration of the aspects and not limitation thereof.

FIG. 1 is a diagram illustrating the difference in height between two example copper pillar bumps, according to aspects of the disclosure.

FIG. 2 is a diagram illustrating a selectively boosted copper pillar bump, according to aspects of the disclosure.

FIG. 3 illustrates various stages of manufacturing copper pillar bumps with boosting pads, according to aspects of the disclosure.

FIG. 4 illustrates an example method of selectively boosting conductive pillar bumps, according to aspects of the disclosure.

### DETAILED DESCRIPTION

Aspects of the disclosure are provided in the following description and related drawings directed to various examples provided for illustration purposes. Alternate aspects may be devised without departing from the scope of the disclosure. Additionally, well-known elements of the disclosure will not be described in detail or will be omitted so as not to obscure the relevant details of the disclosure.

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage or mode of operation.

Those of skill in the art will appreciate that the information and signals described below may be represented using any of a variety of different technologies and techniques. For example, data, instructions, commands, information, signals, bits, symbols, and chips that may be referenced throughout the description below may be represented by voltages, currents, electromagnetic waves, magnetic fields or particles, optical fields or particles, or any combination thereof, depending in part on the particular application, in part on the desired design, in part on the corresponding technology, etc.

Further, some aspects are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, the sequence(s) of actions described herein can be considered to be embodied entirely within any form of non-transitory computer-readable storage medium having stored therein a corresponding set of computer instructions that, upon execution, would cause or instruct an associated processor of a device to perform the functionality described herein. Thus, the various aspects of the disclosure may be embodied in a number of different forms, all of which have been contemplated to be within the scope of the claimed subject matter. In addition, for each of the aspects described herein, the corresponding form of any such aspects may be described herein as, for example, “logic configured to” perform the described action.

Copper pillar bumps are used to connect various package components to the die in advanced packaging processes. Bump coplanarity is an important aspect of ensuring reliable connections. Bump coplanarity is essentially a measure of flatness, and more specifically, a measurement of the variation in bump height. A bump that is not tall enough will not connect to a package component, while one that is too tall may prevent the connections of neighboring bumps. As such, any height unevenness in a bump array may affect wafer probing, flip-chip assembly, electronics board assembly, and ultimately, reliability. Coplanarity becomes particularly important in the context of increasing bump densities in high-performance computing products and other advanced packaging applications.

Differences in bump height (i.e., coplanarity) may be a byproduct of the manufacturing process. For example, due to manufacturing tolerances, there may be some variation in the amount of copper deposited to build the copper pillars. Bump coplanarity may also depend on the bump density. For example, the same die may have different bump densities across different regions of the die (where different components are attached to the die in the different regions). Generally, smaller bumps allow for a smaller bump pitch (i.e., the center-to-center distance between bumps), while larger bumps need a larger pitch. As such, where the same die includes different regions having different bump densities, there may be a difference in coplanarity between the different bump regions (also referred to as bump arrays).

The following table illustrates the differences in bump densities for two different dies, referred to as “Die A” and “Die B.”

TABLE 1

| Parameter | | Die A | Die B |
|---|---|---|---|
| Die Size | | 16.892 × 9.892 | 9.892 × 12.892 |
| | | (167 mm²) | (128 mm²) |
| Bump Count | | 23519 | 10848 |
| Bump Stackup | | Cu 13 μm/Ni 2 μm/Cu 2 μm/LF 15 μm | |
| 25 μm UBM | Bump Count | 4736 | 4736 |
| | Bump Pitch | 45 μm | 45 μm |
| | Bump Density | 25% @ | 25% @ |
| | | 1000 μm² | 1000 μm² |
| 35 μm UBM | Bump Count | 18783 | 6112 |
| | Bump Pitch | 90 μm | 90 μm @ peripheral |
| | | | 140 μm @ core |
| | Bump Density | 12.3% @ | 6% @ 1000 |
| | | 1000 μm² | μm² @ core |

In the above table, the bump stackup row indicates how the copper pillar bumps were manufactured. The traditional approach to bump formation is to plate (i.e., deposit one or more metal deposition layers, or “plates,” onto the die) all bumps on the die at the same time in one or more plating steps (where each step deposits another layer/plate). Bumps are typically plated onto an under bump metallization (UBM) layer (either 25 microns (μm) or 35 μm thick for the dies in Table 1) that is plated onto the die pads. For the example dies in Table 1, the copper pillar bumps were plated onto the UBM layer by first depositing a 13 μm layer of copper (Cu) on the UBM layer, then a 2 μm layer of nickel (Ni), then a 2 μm layer of copper (Cu), then a 15 μm layer of lead free (LF) solder.

Note that “plating” is the process of depositing one or more layers of metal onto a substrate (e.g., a silicon wafer). Plating may also be referred to as “electroplating” or “electrodeposition.”

The following table provides the variation in bump height and coplanarity for the two dies in Table 1. More specifically, the following table provides the maximum (Max), minimum (Min), average (Avg), and standard deviation (Std) of the bump height and coplanarity (COP) for the two dies.

TABLE 2

| | | Die A | | | | Die B | | | |
|---|---|---|---|---|---|---|---|---|---|
| 100% 3D | | Max | Min | Avg | Std | Max | Min | Avg | Std |
| 25 μm | Bump | 30.49 | 26.51 | 28.76 | 0.61 | 31.82 | 28.67 | 30.79 | 0.47 |
| UBM | Height | | | | | | | | |
| | Bump | 7.05 | 3.38 | 4.81 | 0.64 | 6.48 | 3.46 | 4.80 | 0.50 |
| | COP | | | | | | | | |
| 35 μm | Bump | 33.82 | 31.51 | 32.97 | 0.41 | 36.70 | 31.96 | 35.74 | 0.52 |
| UBM | Height | | | | | | | | |
| | Bump | 8.51 | 4.13 | 4.93 | 0.40 | 7.95 | 4.04 | 5.13 | 0.45 |
| | COP | | | | | | | | |
| All | Bump | 33.04 | 30.49 | 32.14 | 0.41 | 33.91 | 30.05 | 33.10 | 0.47 |
| | Height | | | | | | | | |
| | Bump | 9.75 | 7.14 | 8.63 | 0.51 | 9.89 | 7.75 | 9.08 | 0.41 |
| | COP | | | | | | | | |

In the above table, the average bump height gap for Die A is 4.21 and 4.95 for Die B. This average is across both the 25 μm UBM and the 35 μm UBM designs.

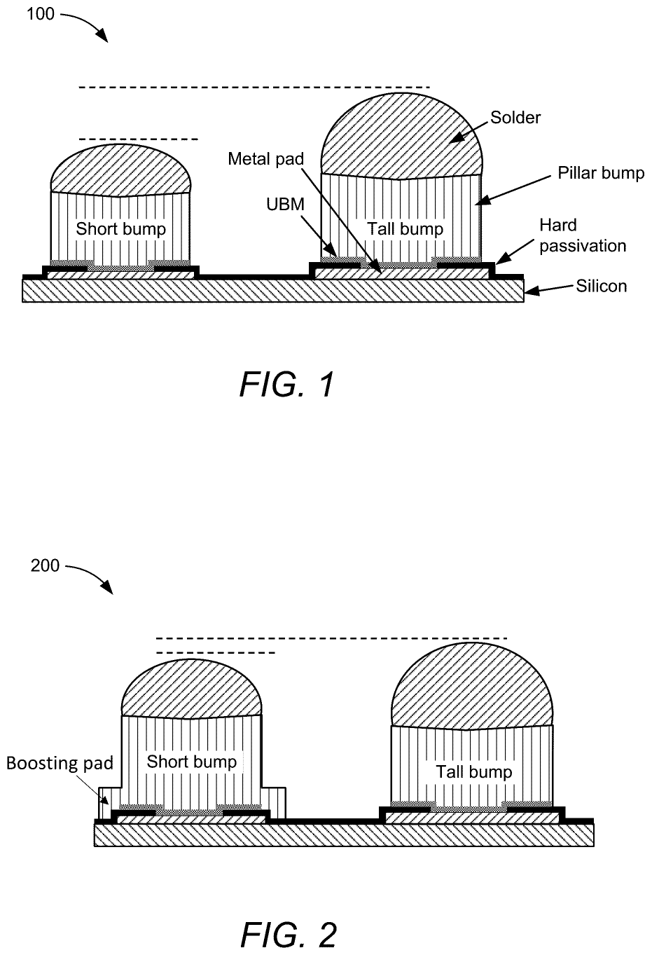

FIG. 1 is a diagram 100 illustrating the difference in height between two example copper pillar bumps, according to aspects of the disclosure. As shown in FIG. 1, the bumps are plated onto a layer of silicon (the die). First, metal pads (die pads) are plated or otherwise deposited onto the silicon where the bumps will be attached. Next, a hard passivation layer is deposited over the metal pads and the exposed silicon. The UBM layer is then plated or otherwise deposited on the passivation layer over the metal pads. The copper pillar bumps are then plated or otherwise deposited onto the UBM layer. As described above with reference to Table 1, the copper pillar bumps may be composed of one or more layers (i.e., plates) of copper (and optionally nickel). Alternatively, the copper pillar bumps may be some other conductive material, such as aluminum (Al), tin (Sn), nickel (Ni), gold (Au), silver (Ag), and/or other suitable electrically conductive material, as is known in the art. Finally, solder is deposited on the copper pillar bumps.

As shown in FIG. 1, the two copper pillar bumps are different heights. The difference in height between the “short” bump and the “tall” bump (indicated by the dashed lines) may be the result of design choice or a byproduct of the manufacturing process. For example, the short bump may be smaller because it is in a region with a higher bump density or because of the type/size of the component to which it will be connected or because UBM layer is thicker under the “tall” bump than the “short” bump. Alternatively, the short bump may be smaller due to insufficient copper deposition when plating the copper pillar bump or the UBM layer. If the difference in height between the two bumps is above some threshold (e.g., 4 μm), it may impact whether or not the short bump can be (reliably) attached to another package component.

The present disclosure provides a technique to decrease the difference in height between copper pillar bumps, thereby improving the coplanarity of the bumps. Specifically, a “boosting pad” can be added under a “short” bump to raise the height of the short bump to within some tolerance threshold of the height of a “tall” bump on the same die.

FIG. 2 is a diagram 200 illustrating a selectively boosted copper pillar bump, according to aspects of the disclosure. The copper pillar bumps illustrated in FIG. 2 may have been manufactured using the same general process as the bumps illustrated in FIG. 1. However, as shown in FIG. 2, a “boosting pad” has been plated or otherwise deposited over the UBM layer under a “short” bump, thereby raising the height of the short bump to within some tolerance threshold (indicated by the dashed lines) of a “tall” bump on the same die. For example, the tolerance threshold may be 4 μm or less.

Referring to the manufacturing process more specifically, as described above with reference to FIG. 1, metal pads (die pads) are plated or otherwise deposited onto the silicon layer (the die) where the bumps will be attached. Next, a hard passivation layer is deposited over the metal pads and the exposed silicon. The UBM layer is then plated or otherwise deposited onto the passivation layer over the metal pads. Next, one or more boosting pads are plated or otherwise deposited onto the UBM layer where short bumps will be attached/deposited in the next step. The boosting pads may be comprised of one or more layers of conductive material. For example, the boosting pads may be one or more layers of copper (Cu), aluminum (Al), tin (Sn), nickel (Ni), gold (Au), silver (Ag), and/or other suitable electrically conductive material. The copper pillar bumps are then plated or otherwise deposited onto the boosting pads and the UBM layer. Like the boosting pads, the copper pillar bumps may be one or more layers of copper (Cu), aluminum (Al), tin (Sn), nickel (Ni), gold (Au), silver (Ag), and/or other suitable electrically conductive material, as is known in the art. Finally, solder is deposited on the copper pillar bumps.

As shown in FIG. 2, the boosting pad is slightly larger in diameter than the copper pillar bump. This is to allow for some misalignment when depositing the copper pillar bump onto the boosting pad. In addition, the boosting pad may be in the shape of a circle, a square, a rectangle, or some other shape.

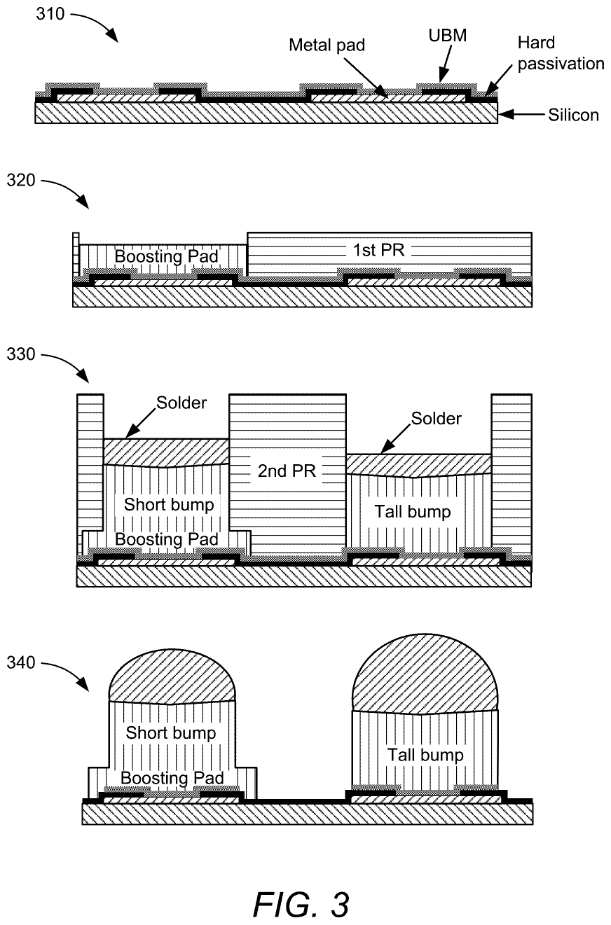

FIG. 3 illustrates various stages of manufacturing copper pillar bumps with boosting pads, according to aspects of the disclosure. At stage 310, a silicon wafer with metal pads and hard passivation layer is received. The UBM layer is then deposited via, for example, sputtering deposition. Sputtering deposition, or sputter coating, is a physical vapor deposition technology that deposits a thin film of metal or other material onto a surface, here, the silicon wafer. Sputtering is the preferred method for layers that are a few thousand Angstroms thick and electroplating is preferred for thicker layers. However, the disclosure is not limited to either of these methods.

At stage 320, a first photoresist (PR) coating is deposited and photo patterned to define the locations and sizes of the boosting pads for the selectively boosted copper pillar bumps. That is, the resulting openings in the first PR coating define where the boosting pads will be plated or otherwise deposited onto the UBM layer. The boosting pads are then plated in the openings in the first PR coating. As described above, the boosting pads may be comprised of one or more layers of conductive material, such as copper (Cu), aluminum (Al), tin (Sn), nickel (Ni), gold (Au), silver (Ag), and/or other suitable electrically conductive material. The first PR coating is then removed.

Note that stage 320 may be repeated to build boosting pads having more than one step. More specifically, the boosting pad illustrated in FIG. 2 is a single step. However, if there are more than two groups of copper pillar bump heights, due, for example, to more than two UBM thicknesses, bump densities, etc., then there may be more than two copper pillar bump heights. As such, some boosting steps may be a single step (for bumps of a first height) other boosting pads may be two steps (for bumps of a second, shorter height), and so on. Each step may be slightly larger in diameter than a subsequently plated step to allow for some misalignment of the steps. That is, the bottom step (deposited on the UBM layer) would be the largest and the top step (to which the copper pillar bump is attached) would be the smallest.

At stage 330, a second PR coating is deposited and photo patterned to define the locations and sizes of the copper pillar bumps. That is, the resulting openings in the second PR coating define where the bumps will be plated onto the UBM layer (for tall bumps) or the boosting pads (for short bumps). The copper pillar bumps are then plated or otherwise deposited in the openings in the second PR coating. Likewise, solder is plated or otherwise deposited on the copper pillar bumps in the openings defined by the second PR coating.

At stage 340, the second PR coating is removed, the UBM layer is etched (to prevent it from extending beyond the bases of the boosting pads or copper pillar bumps), and the solder is reflowed (heated) to round the solder into bumps.

As will be appreciated, selectively boosting certain copper pillar bumps overcomes, or at least reduces, the bump size and bump density problem and improves bump coplanarity compared to whole bump stackup plating. In addition, as will be appreciated, the techniques described herein can be utilized in semiconductor devices incorporated into any number of different electronic devices.

FIG. 4 illustrates an example method 400 of selectively boosting conductive pillar bumps, according to aspects of the disclosure. The method 400 may be performed by various manufacturing machinery, as is known in the art. The method 400 may also be stored as instructions on a (non-transitory) computer-readable medium, where the various manufacturing machinery execute the stored instructions to perform the method 400.

An operation 410 of method 400 comprises attaching a UBM layer to a plurality of metal pads, as at stage 310 of FIG. 3.

An operation 420 of method 400 comprises attaching a first set of boosting pads to a first portion of the UBM layer attached to a first set of the plurality of metal pads, as at stage 320 of FIG. 3.

An operation 430 of method 400 comprises attaching a first set of conductive pillar bumps to the first set of boosting pads, as at stage 330 of FIG. 3, wherein each conductive pillar bump of the first set of conductive pillar bumps is attached to a single boosting pad of the first set of boosting pads.

An operation 440 of method 400 comprises attaching a second set of conductive pillar bumps to a second portion of the UBM layer attached to a second set of the plurality of metal pads, as at stage 330 of FIG. 3, wherein each conductive pillar bump of the second set of conductive pillar bumps is attached to a single metal pad of the second set of metal pads, wherein heights of the first set of conductive pillar bumps are shorter than heights of the second set of conductive pillar bumps, and wherein heights of the first set of boosting pads plus the heights of the first set of conductive pillar bumps are within a tolerance threshold of the heights of the second set of conductive pillar bumps.

An operation 450 comprises attaching solder to the first set of conductive pillar bumps and the second set of conductive pillar bumps, as at stage 330 of FIG. 3.

As will be appreciated, a technical advantage of the method 400 is that selectively boosting certain copper pillar bumps improves bump coplanarity compared to whole bump stackup plating. In addition, compared to traditional whole bump stackup plating, another advantage is lower cost due to the thinner PR thickness and shorter plating time for the boosting pad plating.

In the detailed description above it can be seen that different features are grouped together in examples. This manner of disclosure should not be understood as an intention that the example clauses have more features than are explicitly mentioned in each clause. Rather, the various aspects of the disclosure may include fewer than all features of an individual example clause disclosed. Therefore, the following clauses should hereby be deemed to be incorporated in the description, wherein each clause by itself can stand as a separate example. Although each dependent clause can refer in the clauses to a specific combination with one of the other clauses, the aspect(s) of that dependent clause are not limited to the specific combination. It will be appreciated that other example clauses can also include a combination of the dependent clause aspect(s) with the subject matter of any other dependent clause or independent clause or a combination of any feature with other dependent and independent clauses. The various aspects disclosed herein expressly include these combinations, unless it is explicitly expressed or can be readily inferred that a specific combination is not intended (e.g., contradictory aspects, such as defining an element as both an electrical insulator and an electrical conductor). Furthermore, it is also intended that aspects of a clause can be included in any other independent clause, even if the clause is not directly dependent on the independent clause.

Implementation examples are described in the following numbered clauses:

Clause 1. An apparatus, comprising: a plurality of metal pads; an under bump metallization (UBM) layer attached to the plurality of metal pads; a first set of boosting pads attached to a first portion of the UBM layer attached to a first set of the plurality of metal pads; a first set of conductive pillar bumps attached to the first set of boosting pads, wherein each conductive pillar bump of the first set of conductive pillar bumps is attached to a single boosting pad of the first set of boosting pads; a second set of conductive pillar bumps attached to a second portion of the UBM layer attached to a second set of the plurality of metal pads, wherein each conductive pillar bump of the second set of conductive pillar bumps is attached to a single metal pad of the second set of metal pads, wherein heights of the first set of conductive pillar bumps are shorter than heights of the second set of conductive pillar bumps, and wherein heights of the first set of boosting pads plus the heights of the first set of conductive pillar bumps are within a tolerance threshold of the heights of the second set of conductive pillar bumps; and solder attached to the first set of conductive pillar bumps and the second set of conductive pillar bumps.

Clause 2. The apparatus of clause 1, wherein diameters of the first set of boosting pads are larger than diameters of the first set of conductive pillar bumps.

Clause 3. The apparatus of any of clauses 1 to 2, wherein each boosting pad of the first set of boosting pads comprises one or more steps.

Clause 4. The apparatus of any of clauses 1 to 3, further comprising: a third set of conductive pillar bumps attached to a second set of boosting pads.

Clause 5. The apparatus of clause 4, wherein: each boosting pad of the first set of boosting pads consists of a single step, each boosting pad of the second set of boosting pads comprises two or more steps, and heights of the third set of conductive pillar bumps are shorter than the heights of the first set of conductive pillar bumps.

Clause 6. The apparatus of clause 5, wherein each step of the two or more steps of the second set of boosting pads is larger in diameter than a subsequent step of the two or more steps.

Clause 7. The apparatus of any of clauses 1 to 6, wherein the tolerance threshold is 4 microns or less.

Clause 8. The apparatus of any of clauses 1 to 7, further comprising: a hard passivation layer deposited on the plurality of metal pads.

Clause 9. The apparatus of any of clauses 1 to 8, wherein the first set of boosting pads comprise one or more layers of copper (Cu), aluminum (Al), tin (Sn), nickel (Ni), gold (Au), silver (Ag), or any combination thereof.

Clause 10. The apparatus of any of clauses 1 to 9, wherein the first set of conductive pillar bumps and the second set of conductive pillar bumps comprise one or more layers of copper (Cu), aluminum (Al), tin (Sn), nickel (Ni), gold (Au), silver (Ag), or any combination thereof.

Clause 11. A method of selectively boosting conductive pillar bumps, comprising: attaching an under bump metallization (UBM) layer to a plurality of metal pads; attaching a first set of boosting pads to a first portion of the UBM layer attached to a first set of the plurality of metal pads; attaching a first set of conductive pillar bumps to the first set of boosting pads, wherein each conductive pillar bump of the first set of conductive pillar bumps is attached to a single boosting pad of the first set of boosting pads; attaching a second set of conductive pillar bumps to a second portion of the UBM layer attached to a second set of the plurality of metal pads, wherein each conductive pillar bump of the second set of conductive pillar bumps is attached to a single metal pad of the second set of metal pads, wherein heights of the first set of conductive pillar bumps are shorter than heights of the second set of conductive pillar bumps, and wherein heights of the first set of boosting pads plus the heights of the first set of conductive pillar bumps are within a tolerance threshold of the heights of the second set of conductive pillar bumps; and attaching solder to the first set of conductive pillar bumps and the second set of conductive pillar bumps.

Clause 12. The method of clause 11, wherein attaching the first set of boosting pads comprises: applying a photoresist coating to the UBM layer; photo patterning the photoresist coating to create openings in the photoresist coating for the first set of boosting pads; plating the first set of boosting pads in the openings in the photoresist coating; and removing the photoresist coating.

Clause 13. The method of any of clauses 11 to 12, wherein attaching the first set of conductive pillar bumps to the first set of boosting pads comprises: applying a photoresist coating to at least the first set of boosting pads; photo patterning the photoresist coating to create openings in the photoresist coating for the first set of conductive pillar bumps; plating the first set of conductive pillar bumps into the openings in the photoresist coating; and removing the photoresist coating.

Clause 14. The method of clause 13, wherein attaching the solder to the first set of conductive pillar bumps comprises: depositing the solder into the openings in the photoresist coating; and reflowing the solder.

Clause 15. The method of any of clauses 11 to 14, wherein attaching the second set of conductive pillar bumps comprises: applying a photoresist coating to at least the UBM layer; photo patterning the photoresist coating to create openings in the photoresist coating for the second set of conductive pillar bumps; plating the second set of conductive pillar bumps into the openings in the photoresist coating; and removing the photoresist coating.

Clause 16. The method of clause 15, wherein attaching the solder to the second set of conductive pillar bumps comprises: depositing the solder into the openings in the photoresist coating; and reflowing the solder.

Clause 17. The method of any of clauses 11 to 16, further comprising: attaching a third set of conductive pillar bumps to a second set of boosting pads.

Clause 18. The method of clause 17, wherein: each boosting pad of the first set of boosting pads consists of a single step, each boosting pad of the second set of boosting pads comprises two or more steps, and heights of the third set of conductive pillar bumps are shorter than the heights of the first set of conductive pillar bumps.

Clause 19. The method of clause 18, wherein each step of the two or more steps of the second set of boosting pads is larger in diameter than a subsequent step of the two or more steps.

Clause 20. The method of any of clauses 11 to 19, wherein diameters of the first set of boosting pads are larger than diameters of the first set of conductive pillar bumps.

Clause 21. The method of any of clauses 11 to 20, wherein each boosting pad of the first set of boosting pads comprises one or more steps.

Clause 22. The method of any of clauses 11 to 21, wherein the tolerance threshold is 4 microns or less.

Clause 23. The method of any of clauses 11 to 22, further comprising: depositing a hard passivation layer on the plurality of metal pads.

Clause 24. The method of any of clauses 11 to 23, wherein the first set of boosting pads comprise one or more layers of copper (Cu), aluminum (Al), tin (Sn), nickel (Ni), gold (Au), silver (Ag), or any combination thereof.

Clause 25. The method of any of clauses 11 to 24, wherein the first set of conductive pillar bumps and the second set of conductive pillar bumps comprise one or more layers of copper (Cu), aluminum (Al), tin (Sn), nickel (Ni), gold (Au), silver (Ag), or any combination thereof.

Clause 26. A non-transitory computer-readable medium storing computer-executable instructions that, when executed by one or more apparatuses, cause the one or more apparatuses to: attach an under bump metallization (UBM) layer to a plurality of metal pads; attach a first set of boosting pads to a first portion of the UBM layer attached to a first set of the plurality of metal pads; attach a first set of conductive pillar bumps to the first set of boosting pads, wherein each conductive pillar bump of the first set of conductive pillar bumps is attached to a single boosting pad of the first set of boosting pads; attach a second set of conductive pillar bumps to a second portion of the UBM layer attached to a second set of the plurality of metal pads, wherein each conductive pillar bump of the second set of conductive pillar bumps is attached to a single metal pad of the second set of metal pads, wherein heights of the first set of conductive pillar bumps are shorter than heights of the second set of conductive pillar bumps, and wherein heights of the first set of boosting pads plus the heights of the first set of conductive pillar bumps are within a tolerance threshold of the heights of the second set of conductive pillar bumps; and attach solder to the first set of conductive pillar bumps and the second set of conductive pillar bumps.

Clause 27. The non-transitory computer-readable medium of clause 26, wherein the computer-executable instructions that, when executed by the one or more apparatuses, cause the one or more apparatuses to attach the first set of boosting pads comprise computer-executable instructions that, when executed by the one or more apparatuses, cause the one or more apparatuses to: apply a photoresist coating to the UBM layer; photo pattern the photoresist coating to create openings in the photoresist coating for the first set of boosting pads; plate the first set of boosting pads in the openings in the photoresist coating; and remove the photoresist coating.

Clause 28. The non-transitory computer-readable medium of any of clauses 26 to 27, wherein the computer-executable instructions that, when executed by the one or more apparatuses, cause the one or more apparatuses to attach the first set of conductive pillar bumps to the first set of boosting pads comprise computer-executable instructions that, when executed by the one or more apparatuses, cause the one or more apparatuses to: apply a photoresist coating to at least the first set of boosting pads; photo pattern the photoresist coating to create openings in the photoresist coating for the first set of conductive pillar bumps; plate the first set of conductive pillar bumps into the openings in the photoresist coating; and remove the photoresist coating.

Clause 29. The non-transitory computer-readable medium of clause 28, wherein the computer-executable instructions that, when executed by the one or more apparatuses, cause the one or more apparatuses to attach the solder to the first set of conductive pillar bumps comprise computer-executable instructions that, when executed by the one or more apparatuses, cause the one or more apparatuses to: deposit the solder into the openings in the photoresist coating; and reflow the solder.

Clause 30. The non-transitory computer-readable medium of any of clauses 26 to 29, wherein the computer-executable instructions that, when executed by the one or more apparatuses, cause the one or more apparatuses to attach the second set of conductive pillar bumps comprise computer-executable instructions that, when executed by the one or more apparatuses, cause the one or more apparatuses to: apply a photoresist coating to at least the UBM layer; photo pattern the photoresist coating to create openings in the photoresist coating for the second set of conductive pillar bumps; plate the second set of conductive pillar bumps into the openings in the photoresist coating; and remove the photoresist coating.

Clause 31. The non-transitory computer-readable medium of clause 30, wherein the computer-executable instructions that, when executed by the one or more apparatuses, cause the one or more apparatuses to attach the solder to the second set of conductive pillar bumps comprise computer-executable instructions that, when executed by the one or more apparatuses, cause the one or more apparatuses to: deposit the solder into the openings in the photoresist coating; and reflow the solder.

Clause 32. The non-transitory computer-readable medium of any of clauses 26 to 31, further comprising computer-executable instructions that, when executed by the one or more apparatuses, cause the one or more apparatuses to: attach a third set of conductive pillar bumps to a second set of boosting pads.

Clause 33. The non-transitory computer-readable medium of clause 32, wherein: each boosting pad of the first set of boosting pads consists of a single step, each boosting pad of the second set of boosting pads comprises two or more steps, and heights of the third set of conductive pillar bumps are shorter than the heights of the first set of conductive pillar bumps.

Clause 34. The non-transitory computer-readable medium of clause 33, wherein each step of the two or more steps of the second set of boosting pads is larger in diameter than a subsequent step of the two or more steps.

Clause 35. The non-transitory computer-readable medium of any of clauses 26 to 34, wherein diameters of the first set of boosting pads are larger than diameters of the first set of conductive pillar bumps.

Clause 36. The non-transitory computer-readable medium of any of clauses 26 to 35, wherein each boosting pad of the first set of boosting pads comprises one or more steps.

Clause 37. The non-transitory computer-readable medium of any of clauses 26 to 36, wherein the tolerance threshold is 4 microns or less.

Clause 38. The non-transitory computer-readable medium of any of clauses 26 to 37, further comprising computer-executable instructions that, when executed by the one or more apparatuses, cause the one or more apparatuses to: depositing a hard passivation layer on the plurality of metal pads.

Clause 39. The non-transitory computer-readable medium of any of clauses 26 to 38, wherein the first set of boosting pads comprise one or more layers of copper (Cu), aluminum (Al), tin (Sn), nickel (Ni), gold (Au), silver (Ag), or any combination thereof.

Clause 40. The non-transitory computer-readable medium of any of clauses 26 to 39, wherein the first set of conductive pillar bumps and the second set of conductive pillar bumps comprise one or more layers of copper (Cu), aluminum (Al), tin (Sn), nickel (Ni), gold (Au), silver (Ag), or any combination thereof.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a general purpose processor, a DSP, an ASIC, an FPGA, or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The methods, sequences and/or algorithms described in connection with the aspects disclosed herein may be embodied directly in hardware, in a software module executed by a processor, or in a combination of the two. A software module may reside in random access memory (RAM), flash memory, read-only memory (ROM), erasable programmable ROM (EPROM), electrically erasable programmable ROM (EEPROM), registers, hard disk, a removable disk, a CD-ROM, or any other form of storage medium known in the art. An example storage medium is coupled to the processor such that the processor can read information from, and write information to, the storage medium. In the alternative, the storage medium may be integral to the processor. The processor and the storage medium may reside in an ASIC. The ASIC may reside in a user terminal (e.g., UE). In the alternative, the processor and the storage medium may reside as discrete components in a user terminal.

In one or more example aspects, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

While the foregoing disclosure shows illustrative aspects of the disclosure, it should be noted that various changes and modifications could be made herein without departing from the scope of the disclosure as defined by the appended claims. The functions, steps and/or actions of the method claims in accordance with the aspects of the disclosure described herein need not be performed in any particular order. Furthermore, although elements of the disclosure may be described or claimed in the singular, the plural is contemplated unless limitation to the singular is explicitly stated.

What is claimed is:

1. An apparatus, comprising:
a plurality of metal pads;
an under bump metallization (UBM) layer attached to the plurality of metal pads;
a first set of boosting pads attached to a first portion of the UBM layer attached to a first set of the plurality of metal pads;
a first set of conductive pillar bumps attached to the first set of boosting pads, wherein each conductive pillar bump of the first set of conductive pillar bumps is attached to a single boosting pad of the first set of boosting pads;
a second set of conductive pillar bumps attached to a second portion of the UBM layer attached to a second set of the plurality of metal pads, wherein each conductive pillar bump of the second set of conductive pillar bumps is attached to a single metal pad of the second set of metal pads, wherein heights of the first set of conductive pillar bumps are shorter than heights of the second set of conductive pillar bumps, and wherein heights of the first set of boosting pads plus the heights of the first set of conductive pillar bumps are within a tolerance threshold of the heights of the second set of conductive pillar bumps; and
solder attached to the first set of conductive pillar bumps and the second set of conductive pillar bumps.

2. The apparatus of claim 1, wherein diameters of the first set of boosting pads are larger than diameters of the first set of conductive pillar bumps.

3. The apparatus of claim 1, wherein each boosting pad of the first set of boosting pads comprises one or more steps.

4. The apparatus of claim 1, further comprising:
a third set of conductive pillar bumps attached to a second set of boosting pads.

5. The apparatus of claim 4, wherein:
each boosting pad of the first set of boosting pads consists of a single step,
each boosting pad of the second set of boosting pads comprises two or more steps, and
heights of the third set of conductive pillar bumps are shorter than the heights of the first set of conductive pillar bumps.

6. The apparatus of claim 5, wherein each step of the two or more steps of the second set of boosting pads is larger in diameter than a subsequent step of the two or more steps.

7. The apparatus of claim 1, wherein the tolerance threshold is 4 microns or less.

8. The apparatus of claim 1, further comprising:
a hard passivation layer deposited on the plurality of metal pads.

9. The apparatus of claim 1, wherein the first set of boosting pads comprise one or more layers of copper (Cu), aluminum (Al), tin (Sn), nickel (Ni), gold (Au), silver (Ag), or any combination thereof.

10. The apparatus of claim 1, wherein the first set of conductive pillar bumps and the second set of conductive pillar bumps comprise one or more layers of copper (Cu), aluminum (Al), tin (Sn), nickel (Ni), gold (Au), silver (Ag), or any combination thereof.

11. A method of selectively boosting conductive pillar bumps, comprising:
attaching an under bump metallization (UBM) layer to a plurality of metal pads;
attaching a first set of boosting pads to a first portion of the UBM layer attached to a first set of the plurality of metal pads;
attaching a first set of conductive pillar bumps to the first set of boosting pads, wherein each conductive pillar bump of the first set of conductive pillar bumps is attached to a single boosting pad of the first set of boosting pads;
attaching a second set of conductive pillar bumps to a second portion of the UBM layer attached to a second set of the plurality of metal pads, wherein each conductive pillar bump of the second set of conductive pillar bumps is attached to a single metal pad of the second set of metal pads, wherein heights of the first set of conductive pillar bumps are shorter than heights of the second set of conductive pillar bumps, and wherein heights of the first set of boosting pads plus the heights of the first set of conductive pillar bumps are within a tolerance threshold of the heights of the second set of conductive pillar bumps; and
attaching solder to the first set of conductive pillar bumps and the second set of conductive pillar bumps.

12. The method of claim 11, wherein attaching the first set of boosting pads comprises:
applying a photoresist coating to the UBM layer;
photo patterning the photoresist coating to create openings in the photoresist coating for the first set of boosting pads;
plating the first set of boosting pads in the openings in the photoresist coating; and
removing the photoresist coating.

13. The method of claim 11, wherein attaching the first set of conductive pillar bumps to the first set of boosting pads comprises:
applying a photoresist coating to at least the first set of boosting pads;
photo patterning the photoresist coating to create openings in the photoresist coating for the first set of conductive pillar bumps;
plating the first set of conductive pillar bumps into the openings in the photoresist coating; and
removing the photoresist coating.

14. The method of claim 13, wherein attaching the solder to the first set of conductive pillar bumps comprises:
depositing the solder into the openings in the photoresist coating; and
reflowing the solder.

15. The method of claim 11, wherein attaching the second set of conductive pillar bumps comprises:
applying a photoresist coating to at least the UBM layer;
photo patterning the photoresist coating to create openings in the photoresist coating for the second set of conductive pillar bumps;
plating the second set of conductive pillar bumps into the openings in the photoresist coating; and
removing the photoresist coating.

16. The method of claim 15, wherein attaching the solder to the second set of conductive pillar bumps comprises:
depositing the solder into the openings in the photoresist coating; and
reflowing the solder.

17. The method of claim 11, further comprising:
attaching a third set of conductive pillar bumps to a second set of boosting pads.

18. The method of claim 17, wherein:
each boosting pad of the first set of boosting pads consists of a single step,
each boosting pad of the second set of boosting pads comprises two or more steps, and
heights of the third set of conductive pillar bumps are shorter than the heights of the first set of conductive pillar bumps.

19. The method of claim 18, wherein each step of the two or more steps of the second set of boosting pads is larger in diameter than a subsequent step of the two or more steps.

20. The method of claim 11, wherein diameters of the first set of boosting pads are larger than diameters of the first set of conductive pillar bumps.

21. The method of claim 11, wherein each boosting pad of the first set of boosting pads comprises one or more steps.

22. The method of claim 11, wherein the tolerance threshold is 4 microns or less.

23. The method of claim 11, further comprising:
depositing a hard passivation layer on the plurality of metal pads.

24. The method of claim 11, wherein the first set of boosting pads comprise one or more layers of copper (Cu), aluminum (Al), tin (Sn), nickel (Ni), gold (Au), silver (Ag), or any combination thereof.

25. The method of claim 11, wherein the first set of conductive pillar bumps and the second set of conductive pillar bumps comprise one or more layers of copper (Cu), aluminum (Al), tin (Sn), nickel (Ni), gold (Au), silver (Ag), or any combination thereof.

26. A non-transitory computer-readable medium storing computer-executable instructions that, when executed by one or more apparatuses, cause the one or more apparatuses to:
attach an under bump metallization (UBM) layer to a plurality of metal pads;
attach a first set of boosting pads to a first portion of the UBM layer attached to a first set of the plurality of metal pads;
attach a first set of conductive pillar bumps to the first set of boosting pads, wherein each conductive pillar bump of the first set of conductive pillar bumps is attached to a single boosting pad of the first set of boosting pads;
attach a second set of conductive pillar bumps to a second portion of the UBM layer attached to a second set of the plurality of metal pads, wherein each conductive pillar bump of the second set of conductive pillar bumps is attached to a single metal pad of the second set of metal pads, wherein heights of the first set of conductive pillar bumps are shorter than heights of the second set of conductive pillar bumps, and wherein heights of the first set of boosting pads plus the heights of the first set of conductive pillar bumps are within a tolerance threshold of the heights of the second set of conductive pillar bumps; and
attach solder to the first set of conductive pillar bumps and the second set of conductive pillar bumps.

27. The non-transitory computer-readable medium of claim 26, wherein the computer-executable instructions that, when executed by the one or more apparatuses, cause the one or more apparatuses to attach the first set of boosting pads comprise computer-executable instructions that, when executed by the one or more apparatuses, cause the one or more apparatuses to:
apply a photoresist coating to the UBM layer;
photo pattern the photoresist coating to create openings in the photoresist coating for the first set of boosting pads;
plate the first set of boosting pads in the openings in the photoresist coating; and
remove the photoresist coating.

28. The non-transitory computer-readable medium of claim 26, wherein the computer-executable instructions that, when executed by the one or more apparatuses, cause the one or more apparatuses to attach the first set of conductive pillar bumps to the first set of boosting pads comprise computer-executable instructions that, when executed by the one or more apparatuses, cause the one or more apparatuses to:
apply a photoresist coating to at least the first set of boosting pads;
photo pattern the photoresist coating to create openings in the photoresist coating for the first set of conductive pillar bumps;
plate the first set of conductive pillar bumps into the openings in the photoresist coating; and
remove the photoresist coating.

29. The non-transitory computer-readable medium of claim 28, wherein the computer-executable instructions that, when executed by the one or more apparatuses, cause the one or more apparatuses to attach the solder to the first set of conductive pillar bumps comprise computer-executable instructions that, when executed by the one or more apparatuses, cause the one or more apparatuses to:
deposit the solder into the openings in the photoresist coating; and
reflow the solder.

30. The non-transitory computer-readable medium of claim 26, wherein the computer-executable instructions that, when executed by the one or more apparatuses, cause the one or more apparatuses to attach the second set of conductive pillar bumps comprise computer-executable instructions that, when executed by the one or more apparatuses, cause the one or more apparatuses to:
apply a photoresist coating to at least the UBM layer;
photo pattern the photoresist coating to create openings in the photoresist coating for the second set of conductive pillar bumps;
plate the second set of conductive pillar bumps into the openings in the photoresist coating; and
remove the photoresist coating.

31. The non-transitory computer-readable medium of claim 30, wherein the computer-executable instructions that, when executed by the one or more apparatuses, cause the one or more apparatuses to attach the solder to the second set of conductive pillar bumps comprise computer-executable instructions that, when executed by the one or more apparatuses, cause the one or more apparatuses to:
deposit the solder into the openings in the photoresist coating; and
reflow the solder.

32. The non-transitory computer-readable medium of claim 26, further comprising computer-executable instructions that, when executed by the one or more apparatuses, cause the one or more apparatuses to:
attach a third set of conductive pillar bumps to a second set of boosting pads.

33. The non-transitory computer-readable medium of claim 32, wherein:
each boosting pad of the first set of boosting pads consists of a single step,
each boosting pad of the second set of boosting pads comprises two or more steps, and
heights of the third set of conductive pillar bumps are shorter than the heights of the first set of conductive pillar bumps.

34. The non-transitory computer-readable medium of claim 33, wherein each step of the two or more steps of the second set of boosting pads is larger in diameter than a subsequent step of the two or more steps.

35. The non-transitory computer-readable medium of claim 26, wherein diameters of the first set of boosting pads are larger than diameters of the first set of conductive pillar bumps.

36. The non-transitory computer-readable medium of claim 26, wherein each boosting pad of the first set of boosting pads comprises one or more steps.

37. The non-transitory computer-readable medium of claim 26, wherein the tolerance threshold is 4 microns or less.

38. The non-transitory computer-readable medium of claim 26, further comprising computer-executable instructions that, when executed by the one or more apparatuses, cause the one or more apparatuses to:
depositing a hard passivation layer on the plurality of metal pads.

39. The non-transitory computer-readable medium of claim 26, wherein the first set of boosting pads comprise one or more layers of copper (Cu), aluminum (Al), tin (Sn), nickel (Ni), gold (Au), silver (Ag), or any combination thereof.

40. The non-transitory computer-readable medium of claim 26, wherein the first set of conductive pillar bumps and the second set of conductive pillar bumps comprise one or more layers of copper (Cu), aluminum (Al), tin (Sn), nickel (Ni), gold (Au), silver (Ag), or any combination thereof.
